(19) United States
(12) Patent Application Publication
(10) Pub. No.: US 2022/0415621 A1
(43) Pub. Date: Dec. 29, 2022

(54) FOCUS RING FOR IMPROVEMENT OF SEMICONDUCTOR PLASMA ETCHING PROCESS

(71) Applicant: ONE SEMICON. CO., LTD., Incheon (KR)

(72) Inventors: Sung Dong CHO, Chuncheon-si (KR); Seung Ho YANG, Incheon (KR); Seong Wan BAE, Incheon (KR); Byeong Su AN, Hwaseong-si (KR)

(21) Appl. No.: 17/899,183

(22) Filed: Aug. 30, 2022

(30) Foreign Application Priority Data
Jun. 9, 2021 (KR) 10-2021-0118528

(51) Int. Cl. H01J 37/32; H01L 21/3065

(52) U.S. Cl. CPC H01J 37/32642; H01L 21/3065

(57) ABSTRACT

The present invention relates to a focus ring for improvement of a semiconductor plasma etching process, which is circular, penetrates vertically into the middle portion thereof, and has a plurality of slots equally spaced apart from one another by a given distance on the edge periphery of the underside thereof in a longitudinal direction thereof, wherein so as to allow a plasma to be dispersed and exhausted uniformly at a fast speed through the slots, each slot becomes increased or decreased in diameter in a direction from top to bottom thereof to thus have a top diameter and a bottom diameter different from each other, and otherwise, each slot is rounded inward from both of top and bottom peripheries thereof.

### CROSS REFERENCE TO RELATED APPLICATION OF THE INVENTION

The present application claims the benefit of Korean Patent Application No. 10-2021-0118528 filed in the Korean Intellectual Property Office on Sep. 6, 2021, the entire contents of which are incorporated herein by reference.

### FIELD OF THE INVENTION

The present invention relates to a focus ring for improvement of a semiconductor plasma etching process, and more specifically, to a focus ring for improving technical limitations in an etching process for a next-generation 10 nm or smaller semiconductor by providing slots structurally and functionally new in shape by means of machining to thus allow a plasma to uniformly react to a layer and a pattern on a wafer at a fast speed and to effectively exhaust by-products generated during the etching process, thereby removing an aging process as a pre-process for building a chamber atmosphere before the etching process, improving the characteristics of etching for a plurality of deep contact holes and the etching uniformity among the plurality of deep contact holes, suppressing the micro loading due to etching non-uniformity, and effectively removing the by-products generated during the etching process.

In specific, the present invention relates to a focus ring for improvement of a semiconductor plasma etching process that is capable of being mounted on an etching chamber, while providing slots new in shape through new machining, thereby removing an aging process, effectively exhausting the by-products generated during an etching process uniformly at a fast speed, shortening the time required for the etching process, and obtaining hole etching uniformity as the important etching process characteristics of a next-generation semiconductor (for example, 126-layer high capacity NAND memory) through the new machining, not through the combination of existing process conditions (for example, pressure, gas combination, RF power, and the like).

### BACKGROUND OF THE RELATED ART

Referring to a semiconductor wafer manufacturing process, first, a wafer is made, and next, an oxidization process is applied to form an oxide layer on a surface of the wafer. After that, a semiconductor circuit is formed on the prepared wafer through a photo process, and then, an etching process is applied to remove the remaining region on the wafer except the circuit pattern and make a pattern in which a semiconductor structure is built. Next, a deposition process is applied to coat a desired molecule or unit material onto the wafer to a thickness of a thin film to have electrical characteristics thereof, and then, a metal interconnection process is applied to interconnect wires with one another so that device operating signals are transmitted well, without being mixed with one another. After that, an electrical die sorting (EDS) test process is performed to check whether chips being in the wafers satisfy their desired qualities, and lastly, an electrical packaging process is performed to protect wiring, power supply, and integrated circuits from external environments and to connect terminals with one another.

A plasma etching process is the process of introducing a gas into a chamber, applying a voltage to top and bottom electrodes, passing the gas through a cathode to generate a plasma, and selectively etching the wafer by means of the plasma, and in the plasma etching process, the amount and quality of plasma are very important. In this case, the amount and quality of plasma depend upon the cathode and a focus ring.

The focus ring for the semiconductor plasma etching process is an important part in the plasma etching process necessarily needed in producing semiconductors, and according to the characteristics of the plasma etching process, the focus ring has to be made of a material having excellent high-temperature deformation resistance, high cleanliness, and high chemical corrosion resistance. Up to now, however, most of focus rings are made of silicon, and accordingly, the silicon focus rings have to be exchanged with new ones every several week to month. Further, the life span of the focus ring is shortened due to continuous increasing of RF power during the etching process to thus cause high exchange costs that become a burden in the industrial field.

In a process where by-products are exhausted after the wafer has been selectively etched, as shown in FIGS. 1 and 2, a conventional focus ring 10 is configured to have slots 11 penetrating vertically, through which a plasma moves, but in this case, each slot 11 has a top diameter and a bottom diameter equal to each other, so that the plasma as well as the by-products is not exhausted uniformly at a fast speed through the slots 11, thereby undesirably causing the non-uniformity of the layer or pattern of the wafer and generating contact hole open failure and micro loading.

Further, in the conventional etching process, process repeatability of wafer-to-wafer is more important as semiconductor patterns become micronized, and to maintain the repeatability of wafer-to-wafer, there is a need to have an aging process through which a chamber atmosphere is built to the same level as in the etching process when a new part or consumable is mounted. The aging process is very similar to the real process and kept for several hours according to products to be made, thereby unnecessarily extending the etching process time and shortening the life spans of the parts.

### SUMMARY OF THE INVENTION

Accordingly, the present invention has been made in view of the above-mentioned problems occurring in the related art, and it is an object of the present invention to provide a focus ring for improvement of a semiconductor plasma etching process that is capable of allowing slots along which a plasma moves to be different in top and bottom diameters thereof or to be rounded inward from top and bottom peripheries thereof, so that the plasma can be exhausted uniformly at a fast speed to minimize the time needed for the etching process and improve etching process uniformity.

It is another object of the present invention to provide a focus ring for improvement of a semiconductor plasma etching process that is capable of removing an aging process to extend the life span thereof, thereby enhancing cost reduction efficiencies.

To accomplish the above-mentioned objects, according to the present invention, there is provided a focus ring for improvement of a semiconductor plasma etching process, which is circular, penetrates vertically into the middle portion thereof, and has a plurality of slots equally spaced apart from one another by a given distance on the edge periphery of the underside thereof in a longitudinal direction thereof, wherein so as to allow a plasma to be dispersed and exhausted uniformly at a fast speed through the slots, each slot becomes increased or decreased in diameter in a direction from top to bottom thereof to thus have a top diameter and a bottom diameter different from each other.

According to the present invention, desirably, each slot is rounded inward from top peripheries thereof to allow the plasma to be dispersed and exhausted uniformly at a fast speed therethrough.

According to the present invention, desirably, each slot is rounded inward from top and bottom peripheries thereof to allow the plasma to be dispersed and exhausted uniformly at a fast speed therethrough.

According to the present invention, desirably, each slot becomes gradually increased in width in a direction from the inside to the outside.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a perspective view showing a general focus ring;

FIG. 2 is a sectional view showing a portion A-A of FIG. 1;

FIG. 3 is a perspective view showing a focus ring for improvement of a semiconductor plasma etching process according to the present invention;

FIG. 4 is a bottom perspective view showing the focus ring for improvement of a semiconductor plasma etching process according to the present invention;

FIGS. 5A and 5B are longitudinal sectional views showing slots of the focus ring for improvement of a semiconductor plasma etching process according to the present invention;

FIGS. 6A and 6B are longitudinal sectional views showing other slots of the focus ring for improvement of a semiconductor plasma etching process according to the present invention; and

FIG. 7 is a transverse sectional view showing still other slots of the focus ring for improvement of a semiconductor plasma etching process according to the present invention.

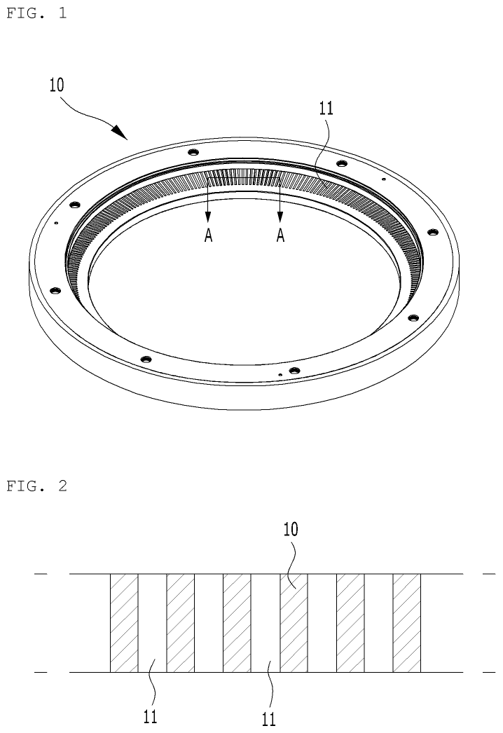

### DETAILED DESCRIPTION OF THE PREFERRED EMBODIMENTS

The present invention may be modified in various ways and may have several exemplary embodiments. Specific exemplary embodiments of the present invention are illustrated in the drawings and described in detail in the detailed description. However, this does not limit the invention within specific embodiments and it should be understood that the invention covers all the modifications, equivalents, and replacements within the idea and technical scope of the invention.

In the drawing figures, the embodiments of the invention may be exaggerated for clarity of illustration, while being not limited to specific forms. It should be noted that the use of particular terminology when describing certain features or aspect of the disclosure should not be taken to imply that the terminology is being re-defined herein to be restricted to include any specific characteristics of the features or aspects of the disclosure with which that terminology is associated.

A term ‘and/or’ includes a combination of a plurality of relevant and described items or any one of a plurality of related and described items. When it is said that one element is described as being “connected” or “coupled” to the other element, one element may be directly connected or coupled to the other element, but it should be understood that another element may be present between the two elements. An expression referencing a singular value additionally refers to a corresponding expression of the plural number, unless explicitly limited otherwise by the context. In this application, terms, such as “comprise”, “include”, or ‘have”, are intended to designate those characteristics, numbers, steps, operations, elements, or parts which are described in the specification, or any combination of them that exist.

In the description, when it is said that a layer, a region, a pattern, or a structure is located “on” or “under” another layer, region, pattern, or structure, it means that one layer may come into contact with another layer as well as yet another layer may exist between the two layers. The relation between the layers is explained with reference to the drawings.

Hereinafter, embodiments of the present invention will be explained in detail with reference to the attached drawings.

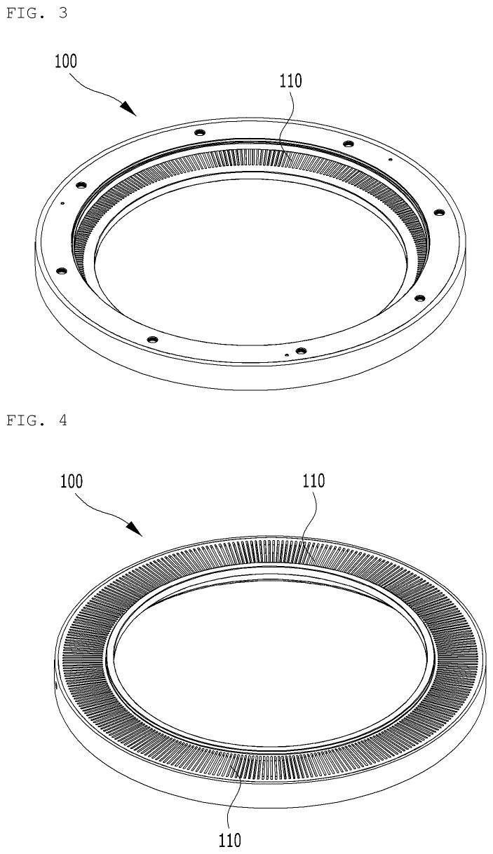

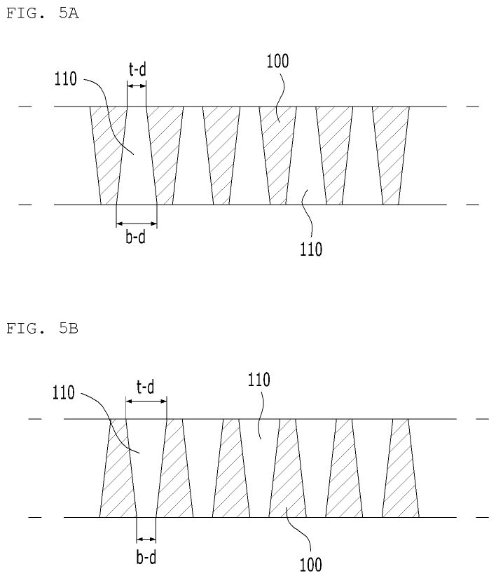

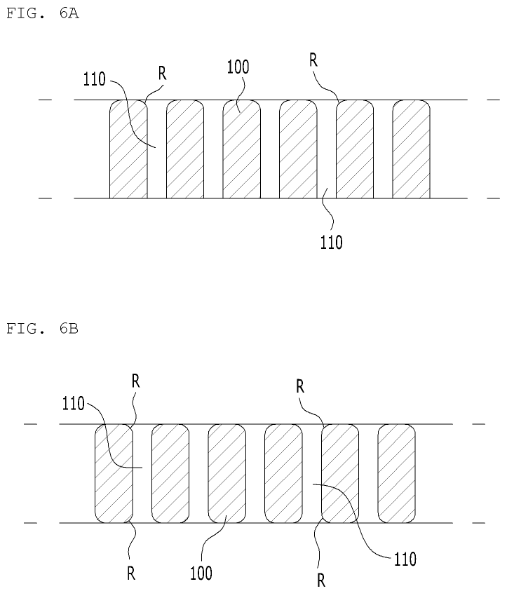

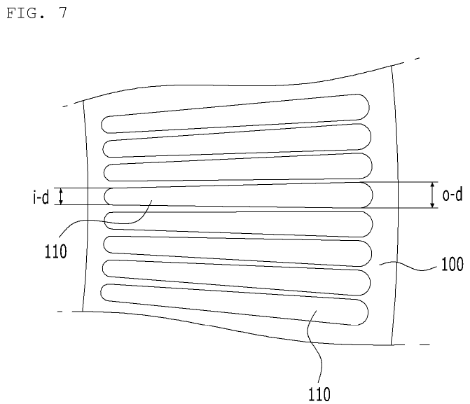

FIG. 3 is a perspective view showing a focus ring for improvement of a semiconductor plasma etching process according to the present invention, FIG. 4 is a bottom perspective view showing the focus ring for improvement of a semiconductor plasma etching process according to the present invention, FIGS. 5A and 5B are longitudinal sectional views showing slots of the focus ring for improvement of a semiconductor plasma etching process according to the present invention, FIGS. 6A and 6B are longitudinal sectional views showing other slots of the focus ring for improvement of a semiconductor plasma etching process according to the present invention, and FIG. 7 is a transverse sectional view showing still other slots of the focus ring for improvement of a semiconductor plasma etching process according to the present invention.

As shown in FIGS. 3 to 7, a focus ring 100 for improvement of a semiconductor plasma etching process according to the present invention is located on the outer periphery of top of an electrostatic chuck (not shown) of a semiconductor etching device.

The focus ring 100 is circular, made of at least any or more materials of silicon, silicon carbide (SiC), boron carbide (B₄C), silica (SiO₂), aluminum oxide (Al₂O₃), alumina, and the like, penetrates vertically into the middle portion thereof, and has a plurality of rectangular slots 110 equally spaced apart from one another by a given distance on the edge periphery of the underside thereof.

As shown in FIGS. 5A and 5B, each slot 110 has a top diameter t-d and a bottom diameter b-d different from each other in a direction along which a plasma moves upon an etching process, so that the plasma can be dispersed and exhausted uniformly at a fast speed.

Like this, the slot 110 may become increased or decreased in diameter toward the bottom thereof in the direction along which the plasma moves.

That is, the bottom width of the slot 110 becomes more increased or decreased than the top width of the slot 110 so as to allow the plasma to be exhausted uniformly at a fast speed through the slot 110, thereby reducing the time needed for the etching process.

For example, if the top diameter t-d of the slot 110 is 2.52 mm, the bottom diameter b-d thereof is 3.014 mm.

Further, as shown in FIGS. 6A and 6B, each slot 110 is subjected to rounding R on top or bottom periphery or both of top and bottom peripheries thereof so as to allow the plasma to be dispersed at a fast speed.

The rounding R of the slot 110 on the top and bottom peripheries thereof is machined with a rounding value of C0.66 (0.66 mm) by means of a chamfering tool (not shown).

As shown in FIG. 7, the slot 110 becomes gradually increased in width in a direction from the inside to the outside.

In this case, the inner diameter i-d of the slot 110 is about ø1.8 to 2.2, and the outer diameter o-d thereof is about ø3.0 to 3.4.

Further, the width of the slot becomes gradually increased by about 1.0 to 1.4° in the direction from the inside to the outside.

Desirably, the inner diameter i-d of the slot 110 is ø2.0, and the outer diameter o-d of the slot 110 is ø3.2. Desirably, the slot 110 becomes gradually increased in width by 1.299° in the direction from the inside to the outside.

The slot 110 is machined by means of a laser, an electric discharge machining tool, a machining center, and the like.

Under the above-mentioned configuration, an explanation of the operations of the focus ring for improvement of the semiconductor plasma etching process according to the present invention will be given below.

The slots 110 are equally spaced apart from one another by the given distance on the edge periphery of the underside of the focus ring 100, so that upon the etching process, they prevent the plasma from being dispersed and control the flow and amount of the plasma, thereby making the etching process to be stably performed.

Further, each slot 110 becomes increased or decreased in diameter in the direction from the top to the bottom thereof to thus have the top diameter t-d and the bottom diameter b-d different from each other, and otherwise, each slot 110 is subjected to the rounding R inward from both of top and bottom peripheries thereof, so that upon the etching process, the plasma can be exhausted through the slot 110 uniformly at a fast speed.

Like this, the top and bottom diameters of each slot 110 are different from each other to allow the plasma to be exhausted at a fast speed, thereby improving the characteristics of the etching process on the wafer, minimizing the etching process time, and needing no pre-process such as aging.

One focus ring has been explained as an example in the above, but in addition thereto, the present invention may be applied to various rings requiring aging.

As mentioned above, the focus ring for improvement of the semiconductor plasma etching process according to the present invention is configured to allow the slots penetrating vertically and moving the plasma therethrough to be different in top and bottom diameters thereof or to be rounded inward from the top and bottom peripheries thereof, so that the plasma can be exhausted uniformly at a fast speed to minimize the occurrence of defects in the etching process, improve the uniformity of the etching process, remove the aging process to shorten the etching process time and maximize work efficiency, and extend the life span of the focus ring to decrease the manufacturing cost of the focus ring.

The present invention may be modified in various ways and may have several exemplary embodiments. Accordingly, it should be understood that the invention covers all the modifications, equivalents, and replacements within the idea and technical scope of the invention. Therefore, the present invention is not to be restricted by the embodiment but only by the appended claims.

What is claimed is:

1. A focus ring for improvement of a semiconductor plasma etching process, which is circular, penetrates vertically into the middle portion thereof, and has a plurality of slots equally spaced apart from one another by a given distance on the edge periphery of the underside thereof in a longitudinal direction thereof, wherein so as to allow a plasma to be dispersed and exhausted uniformly at a fast speed through the slots, each slot becomes increased or decreased in diameter in a direction from top to bottom thereof to thus have a top diameter and a bottom diameter different from each other.

2. The focus ring according to claim 1, wherein each slot is rounded inward from top periphery thereof to allow the plasma to be dispersed and exhausted at the fast speed therethrough.

3. The focus ring according to claim 1, wherein each slot is rounded inward from top and bottom peripheries thereof to allow the plasma to be dispersed and exhausted at the fast speed therethrough.

4. The focus ring according to claim 1, wherein each slot becomes gradually increased in width in a direction from the inside to the outside thereof.
